(19) United States
(12) Patent Application Publication
(10) Pub. No.: US 2026/0027927 A1
(43) Pub. Date: Jan. 29, 2026

(54) ON-BOARD CHARGER AND INVERTER SYSTEM FOR VEHICLES

(71) Applicant: MATTER MOTOR WORKS PRIVATE LIMITED, Ahmedabad (IN)

(72) Inventors: Kumar Prasad TELIKEPALLI, Ahmedabad (IN); Shivam GARG, Ahmedabad (IN); Darshan PANCHAL, Ahmedabad (IN)

(21) Appl. No.: 19/343,027

(22) Filed: Sep. 29, 2025

Related U.S. Application Data
(63) Continuation-in-part of application No. 18/712,810, now Pat. No. 12,447,842.

(30) Foreign Application Priority Data
Nov. 24, 2021 (IN) 202121054085

(51) Int. Cl. B60L 53/24; B60L 3/00; B60L 3/04; B60L 7/14; B60L 53/62; G01R 31/12; G01R 31/52; H02J 7/00; H02J 7/14

(52) U.S. Cl. CPC B60L 53/24; B60L 3/0069; B60L 3/04; B60L 7/14; B60L 53/62; G01R 31/1272; G01R 31/52; H02J 7/0063; H02J 7/0068; H02J 7/1446; B60L 2210/22; B60L 2210/30; B60L 2210/40; B60L 2220/14

(57) ABSTRACT

The present disclosure provides an on-board charger and inverter system (100, 200, 300) for a vehicle. The system comprises a unified charger cum traction inverter (UCCTI) configured for bidirectional conversion between alternating current and direct current, a rechargeable battery coupled to the UCCTI (1, 9, 16), and a dual three-phase permanent magnet synchronous motor (PMSM) (3, 11, 18) having a first three-phase terminal set (3a) coupled to the UCCTI (1, 9, 16) and a second three-phase terminal set (3b) selectively connectable to an external alternating current source (5, 13, 20). A controller (4, 12, 19) configures the dual three-phase PMSM (3, 11, 18) to operate as a transformer during charging or as a propulsion motor during traction. The UCCTI (1, 9, 16) operates in a first charging mode using three-phase alternating current, a second charging mode using single-phase alternating current, a third traction mode supplying three-phase alternating current to the PMSM (3, 11, 18), and a fourth traction mode supplying single-phase alternating current to the PMSM (3, 11, 18), thereby enabling integrated charging and propulsion functions.

### CROSS REFERENCE TO RELATED APPLICTIONS

The present application claims priority from Indian Provisional Patent Application No. 202121054085 filed on 24 Nov. 2021, the entirety of which is incorporated herein by a reference.

### TECHNICAL FIELD

The present disclosure relates generally to an on-board charger and inverter system, and more particularly to an on-board charger cum traction inverter system for electric vehicles that incorporates a dual three-phase permanent magnet synchronous motor configured to perform both transformer and propulsion functions with respect to single-phase or three-phase power supply.

### BACKGROUND

The accelerated adoption of electric vehicles across diverse regions is driving continuous advancements in vehicle powertrain architectures. In particular, integrated on-board systems that combine the functions of charging and traction inversion have become critical to enable efficient utilization of electric power and to reduce overall hardware complexity.

Conventional on-board charger cum inverter systems, while effective in enabling both charging of a battery and propulsion of a traction motor, continue to rely on additional hardware that adds cost, weight, and design constraints. In typical arrangements, separate step-down transformers and filter transformers are incorporated to adapt the alternating current received from external supply sources to levels compatible with battery charging. These bulky components occupy valuable space, increase vehicle mass, and elevate system expense. Moreover, the separation of traction motor hardware from transformer hardware creates redundancy, as both assemblies handle high-power alternating current but cannot substitute for each other. Switching between charging and traction operation further requires dedicated circuit breakers and sensing units, adding wiring complexity, additional points of failure, and cost to the system. A further limitation of current designs is their restricted adaptability to different grid conditions: many architectures are tailored to either single-phase or three-phase input, and supporting both typically necessitates multiple auxiliary devices. These shortcomings collectively constrain system efficiency, scalability, and acceptance in wider markets.

Accordingly, there remains a need for an improved on-board charger and inverter architecture that reduces bulk and duplication of components, simplifies the power path for charging and traction operation, and provides inherent flexibility for operation with both single-phase and three-phase supply sources.

### OBJECT OF THE INVENTION

To provide an on-board charger and inverter system for an electric vehicle that incorporates a dual three-phase permanent magnet synchronous motor configured to function both as a propulsion motor and as a transformer during charging operation.

To provide an on-board charger and inverter system for an electric vehicle that enables direct connection of an external single-phase or three-phase power source to a dedicated terminal set of the dual three-phase permanent magnet synchronous motor, thereby permitting transformer and filter operation without requiring bulky external transformer or filter units.

To provide an on-board charger and inverter system for an electric vehicle that simplifies the overall power conversion path by reducing reliance on separate circuit breakers, sensors, and switching devices otherwise necessary to configure between charging and traction modes.

To provide an on-board charger and inverter system for an electric vehicle that offers flexible operation under single-phase and three-phase supply conditions with reduced component duplication, lower weight, and lower cost.

Other objects and advantages of the system of the present disclosure will be more apparent from the following description when read in conjunction with the accompanying figures, which are not intended to limit the scope of the present disclosure.

### SUMMARY OF THE INVENTION

The aim of the present disclosure is to provide on-board charger and inverter system for a vehicle.

The present disclosure relates an on-board charger and inverter system for a vehicle is provided. The system comprises a unified charger cum traction inverter (UCCTI) configured for bidirectional conversion between alternating current power and direct current power, a rechargeable battery electrically coupled to the UCCTI, and a dual three-phase permanent magnet synchronous motor (PMSM) having a first three-phase terminal set connected to the UCCTI and a second three-phase terminal set selectively connectable to an external alternating current power source. A controller is operatively coupled to the UCCTI and the dual three-phase PMSM and configures the PMSM to function either as a transformer in charging mode or as a propulsion motor in traction mode, while further configuring the UCCTI to operate in four distinct modes of charging and traction with respect to single-phase and three-phase power supply.

The system achieves several technical advantages. By employing the dual three-phase PMSM as both a propulsion motor and a transformer, the architecture eliminates the requirement for bulky external step-down transformers and separate filter transformers, thereby reducing weight, cost, and volume. The integration of transformer functionality within the PMSM reduces redundancy between charging and traction hardware and enhances overall component utilization. The selective coupling of a second terminal set to an external power source simplifies the charging path and minimizes the need for multiple circuit breakers or sensors to switch between modes. Furthermore, the controller-driven configuration enables flexible compatibility with both single-phase and three-phase input sources, improving adaptability in regions with varied grid infrastructures. Collectively, these advantages provide a compact, cost-efficient, and flexible on-board charger and inverter system that supports efficient charging and reliable traction operation in a single integrated arrangement.

The aim of the present disclosure is achieved by the system as defined in the appended independent claim to which reference is made. Advantageous features are set out in the appended dependent claims.

### BRIEF DESCRIPTION OF DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers. Embodiments of the present disclosure will now be described, by way of example only, with reference to the following diagrams wherein:

FIG. 1 shows an electrical single line diagram of an on-board charger and inverter system for a vehicle according to an embodiment of the present invention.

FIG. 2 illustrates an electrical single line diagram of an on-board charger and inverter system for a vehicle according to another embodiment of the present invention.

FIG. 3 illustrates a block diagram of an on-board charger and inverter system for a vehicle according to yet another embodiment of the present invention.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION

The following detailed description illustrates embodiments of the present disclosure and ways in which they can be implemented. Although some modes of carrying out the present disclosure have been disclosed, those skilled in the art would recognise that other embodiments for carrying out or practising the present disclosure are also possible.

The description set forth below in connection with the appended drawings is intended as a description of certain embodiments of an on-board charger and inverter system and is not intended to represent the only forms that may be developed or utilised. The description sets forth the various structures and/or functions in connection with the illustrated embodiments; however, it is to be understood that the disclosed embodiments are merely exemplary of the disclosure that may be embodied in various and alternative forms. The figures are not necessarily to scale; some features may be exaggerated or minimised to show details of particular components. Therefore, specific structural and functional details disclosed herein are not to be interpreted as limiting, but merely as a representative basis for teaching one skilled in the art to variously employ the present invention.

While the disclosure is susceptible to various modifications and alternative forms, specific embodiment thereof has been shown by way of example in the drawings and will be described in detail below. It should be understood, however, that it is not intended to limit the disclosure to the particular forms disclosed, but on the contrary, the disclosure is to cover all modifications, equivalents, and alternatives falling within the scope of the disclosure.

The terms “comprise”, “comprises”, “comprising”, “include(s)”, or any other variations thereof, are intended to cover a non-exclusive inclusion, such that a setup, system that includes a list of components or steps does not comprise only those components or steps but may include other components or steps not expressly listed or inherent to such setup or system. In other words, one or more elements in a system or apparatus preceded by “comprises . . . a” does not, without more constraints, preclude the existence of other elements or additional elements in the system or apparatus.

In the following detailed description of the embodiments of the disclosure, reference is made to the accompanying drawings and which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

The present disclosure will be described herein below with reference to the accompanying drawings. In the following description, well known functions or constructions are not described in detail since they would obscure the description with unnecessary detail.

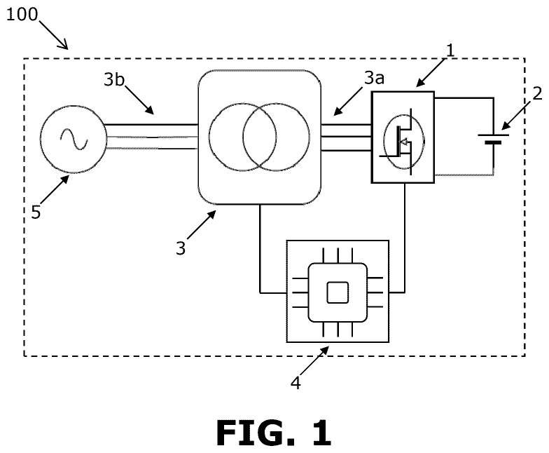

FIG. 1 shows an electrical single line diagram of an on-board charger and inverter system 100 for a vehicle. The system 100 comprises a unified charger cum traction inverter (UCCTI) 1, a rechargeable battery 2, a dual three-phase permanent magnet synchronous motor (PMSM) 3 and a controller 4. The dual three-phase PMSM 3 further comprises a first three-phase terminal set 3a electrically coupled to the UCCTI 1, and a second three-phase terminal set 3b selectively connectable to an external alternating current power source 5.

The UCCTI 1 is configured for bidirectional conversion between alternating current and direct current. In charging operation, the UCCTI 1 converts alternating current supplied through the dual three-phase PMSM 3 into direct current for charging the rechargeable battery 2. In traction operation, the UCCTI 1 converts direct current supplied from the rechargeable battery 2 into alternating current for delivery to the dual three-phase PMSM 3. A technical benefit of the UCCTI 1 is that it integrates both charging and inverter functionality in a single unit, thereby reducing the component count, physical volume, and cost of the system 100. Additionally, the bidirectional configuration of the UCCTI 1 enables seamless switching between charging and propulsion modes, enhancing operational efficiency.

The rechargeable battery 2 is electrically coupled to the UCCTI 1 and provides direct current power to the UCCTI 1 during traction mode. In charging mode, the rechargeable battery 2 stores the direct current output of the UCCTI 1. A technical benefit of the rechargeable battery 2 is that it operates in both charge-accepting and discharge-providing capacities without requiring separate energy storage units, thereby simplifying the energy storage architecture of the vehicle.

The dual three-phase PMSM 3 is a central component of the system 100. It is configured with six electrical terminals forming two three-phase sets. The first three-phase terminal set 3a is electrically coupled to the UCCTI 1, while the second three-phase terminal set 3b is selectively connectable to the external alternating current power source 5. In a charging mode, the dual three-phase PMSM 3 functions as a transformer, where the second three-phase terminal set 3b receives either three-phase alternating current or single-phase alternating current across two terminals. In this role, the PMSM 3 operates as both a step-down transformer to reduce grid voltage to a level suitable for charging and a filter transformer to suppress harmonic distortions in the alternating current. In a traction mode, the PMSM 3 functions as a propulsion motor, wherein the first three-phase terminal set 3a receives alternating current generated by the UCCTI 1 through conversion of direct current stored in the rechargeable battery 2. A technical benefit of the dual three-phase PMSM 3 is that it eliminates the requirement for a separate bulky transformer and filter unit, thereby significantly reducing the system weight and volume. Furthermore, the dual-winding architecture permits redundancy and flexible operation across both single-phase and three-phase grid connections.

The external alternating current power source 5 is selectively connectable to the second three-phase terminal set 3b of the PMSM 3. In a first charging mode, the second three-phase terminal set 3b receives three-phase alternating current from the external power source 5, and the PMSM 3 functions as a step-down transformer and a filter transformer. The alternating current reduced by the PMSM 3 is subsequently converted by the UCCTI 1 into direct current for charging the rechargeable battery 2. In a second charging mode, the second three-phase terminal set 3b receives single-phase alternating current across two terminals from the external power source 5, and the PMSM 3 again functions as the step-down transformer and the filter transformer. The alternating current received in this configuration is converted by the UCCTI 1 into direct current for charging the rechargeable battery 2.

In a third traction mode, the first three-phase terminal set 3a receives three-phase alternating current from the UCCTI 1, the alternating current being converted from the direct current of the rechargeable battery 2, to drive the PMSM 3 in the traction mode. In a fourth traction mode, two terminals of the first three-phase terminal set 3a receive single-phase alternating current from the UCCTI 1, the alternating current being converted from the direct current of the rechargeable battery 2, to drive the PMSM 3 in the traction mode. Through this configuration, the dual three-phase PMSM 3 seamlessly transitions between acting as a transformer during charging and as a motor during traction, with the UCCTI 1 providing the necessary bidirectional conversion across all operating modes.

The controller 4 is operatively coupled to the UCCTI 1 and the dual three-phase PMSM 3. The controller 4 is configured to manage the operation of the PMSM 3 as either a transformer during charging or as a propulsion motor during traction, and to configure the UCCTI 1 to execute the appropriate mode of operation according to the supply input and the traction requirements. A technical benefit of the controller 4 is that it enables intelligent coordination between the PMSM 3 and the UCCTI 1 to achieve flexible multi-mode operation without the need for external switching units or manual intervention. This control integration provides improved system reliability, seamless adaptability to different grid types, and optimized vehicle propulsion performance.

In an embodiment of the invention, the transformer function of the PMSM 3 comprises a step-down transformer function and a filter transformer function. In the step-down transformer function, the PMSM 3 reduces the voltage level of alternating current received at the second three-phase terminal set 3b from the external alternating current power source 5, thereby matching the supply voltage to the level required for safe and efficient charging of the rechargeable battery 2 through the UCCTI 1. A technical benefit of this step-down transformer function is that it eliminates the requirement for a separate bulky step-down transformer, resulting in reduced system size, weight, and manufacturing cost while ensuring compatibility with high-voltage grid supplies. In the filter transformer function, the PMSM 3 suppresses harmonic distortion present in the alternating current provided by the external power source 5, thereby delivering a smoother waveform to the UCCTI 1 for conversion into direct current. A technical benefit of this filter transformer function is that it minimizes switching losses within the UCCTI 1, improves charging efficiency, and prolongs the operational life of the rechargeable battery 2.

In another embodiment, the controller 4 is configured to isolate one three-phase terminal set of the PMSM 3 upon detection of a coil failure. In this arrangement, the controller 4 monitors the operational condition of the windings associated with the PMSM 3, and if a failure or discontinuity in one set of coils is detected, the controller 4 disconnects the affected terminal set from active operation. The PMSM 3 is thereafter operated using the remaining healthy three-phase terminal set, thereby maintaining propulsion or charging functionality without complete system shutdown. A technical benefit of this configuration is that it provides fault tolerance within the PMSM 3, enabling continued operation of the vehicle under degraded conditions. This improves system reliability, reduces the risk of vehicle immobilization due to coil faults, and extends the usable service life of the PMSM 3 by allowing partial but functional operation until maintenance can be performed.

In yet another embodiment of the invention, the PMSM 3 includes harmonic suppression coils that are integrated to filter switching ripple when the PMSM 3 operates in the transformer function. During charging, alternating current from the external power source 5 passes through the second three-phase terminal set 3b, and the PMSM 3 performs the step-down and filter transformer functions before the current is supplied to the UCCTI 1. The harmonic suppression coils reduce high-frequency ripple components introduced by grid disturbances or inverter switching actions, thereby delivering a stabilized alternating current waveform to the UCCTI 1. A technical benefit of incorporating harmonic suppression coils within the PMSM 3 is that it minimizes the electrical stress on the UCCTI 1 during conversion, improves the quality of direct current supplied to the rechargeable battery 2, and reduces electromagnetic interference within the vehicle system 100. This enhances charging efficiency, prolongs battery health, and ensures compliance with electromagnetic compatibility standards.

In still another embodiment, the system 100 further comprises a rotor-position lock configured to immobilize the PMSM 3 during operation in the charging mode. When the second three-phase terminal set 3b of the PMSM 3 is connected to the external alternating current power source 5, the PMSM 3 functions as a transformer to step down and filter the supply prior to conversion by the UCCTI 1. In this state, it is necessary to maintain the mechanical rotor of the PMSM 3 in a fixed position so that the windings act effectively as transformer coils rather than as a rotating machine. The rotor-position lock prevents unintended rotation by mechanically or electromagnetically securing the rotor. A technical benefit of the rotor-position lock is that it ensures stable transformer action, prevents parasitic torque generation, and eliminates mechanical wear of the PMSM 3 during charging operation. A further benefit is that it allows the PMSM 3 to reliably perform dual functions without requiring additional transformer hardware, thereby improving overall system efficiency and lowering maintenance requirements for the system 100.

In a further embodiment, the PMSM 3 is integrated with liquid cooling channels and a plurality of thermal conduction fins to dissipate heat during operation in the transformer function. When the PMSM 3 is connected to the external alternating current power source 5 through the second three-phase terminal set 3b, it performs the step-down and filter transformer roles to condition the alternating current prior to conversion into direct current by the UCCTI 1. This transformer operation introduces thermal loading on the windings and magnetic core of the PMSM 3, in addition to the thermal stress experienced during propulsion operation. The integration of liquid cooling channels allows continuous circulation of coolant through the PMSM 3, while the thermal conduction fins increase surface area to enable efficient heat dissipation into the surrounding environment. A technical benefit of this arrangement is that it prevents overheating of the PMSM 3, stabilizes its electrical characteristics during charging, and extends the durability of the insulation system. Furthermore, effective heat removal enables higher charging currents to be handled without compromising safety, thereby improving the overall efficiency and reliability of the system 100.

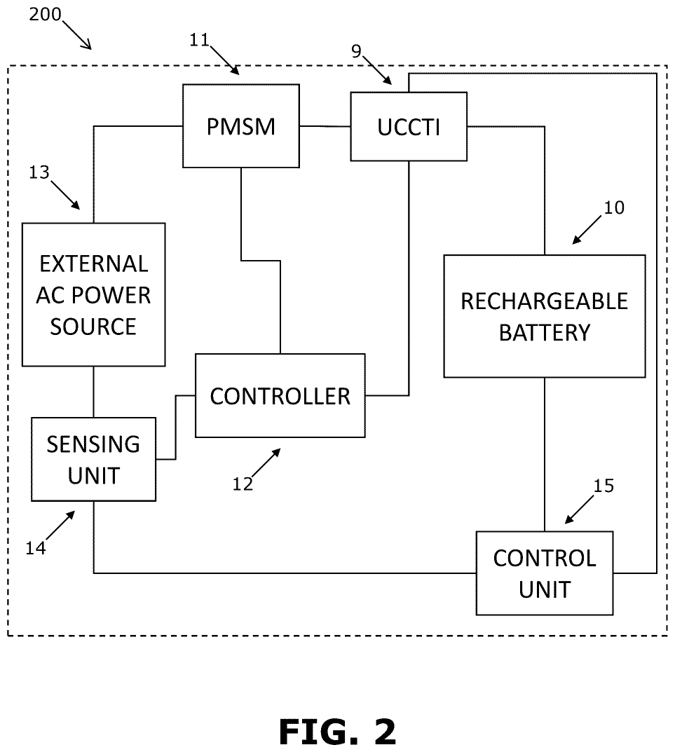

FIG. 2 illustrates an electrical single line diagram of an on-board charger and inverter system 200 for a vehicle. The system 200 comprises a UCCTI 9, a rechargeable battery 10, a dual three-phase PMSM 11, a controller 12, and an external alternating current power source 13. The PMSM 11 comprises a first three-phase terminal set electrically coupled to the UCCTI 9 and a second three-phase terminal set selectively connectable to the external alternating current power source 13. The UCCTI 9 is configured for bidirectional conversion between alternating current and direct current, enabling charging of the rechargeable battery 10 during a charging mode and propulsion of the PMSM 11 during a traction mode. The controller 12 coordinates the operation of the UCCTI 9 and the PMSM 11, thereby enabling operation in the first charging mode, the second charging mode, the third traction mode, and the fourth traction mode described with reference to FIG. 1.

The system 200 further comprises a sensing unit 14 operatively connected to the external alternating current power source 13. The sensing unit 14 is configured to detect at least one grid quality parameter selected from harmonic distortion, voltage sag, and frequency deviation. By directly monitoring the electrical characteristics of the source 13, the sensing unit 14 provides real-time data regarding the stability and quality of the alternating current supplied to the PMSM 11 and the UCCTI 9. A technical benefit of the sensing unit 14 is that it enables the system 200 to anticipate and compensate for grid disturbances before they adversely affect the charging process, thereby improving compatibility with variable power infrastructures.

The sensing unit 14 communicates with a control unit 15 that is coupled to both the rechargeable battery 10 and the UCCTI 9. The control unit 15 adjusts at least one charging parameter selected from a charging current magnitude, a charging voltage level, and a charging rate in response to the values detected by the sensing unit 14. For example, if the sensing unit 14 detects harmonic distortion above a threshold, the control unit 15 instructs the UCCTI 9 to reduce the charging current magnitude; if a voltage sag is detected, the control unit 15 modifies the charging rate to avoid overloading the UCCTI 9; and if a frequency deviation is detected, the control unit 15 adjusts the charging voltage profile to align with the altered supply frequency. A technical benefit of this configuration is that the control unit 15 ensures the charging process is dynamically optimized for efficiency, safety, and battery longevity, while the direct connection to the UCCTI 9 provides immediate execution of adjusted parameters. Referring back to the system 100 shown in FIG. 1, in a preferred embodiment the UCCTI 1 further comprises an isolation monitoring circuit. The isolation monitoring circuit is configured to measure an insulation resistance between at least one high-voltage conductor associated with the UCCTI 1 and a ground during alternating current charging. In this arrangement, when the second three-phase terminal set 3b of the PMSM 3 is connected to the external alternating current power source 5, the isolation monitoring circuit continually evaluates the insulation integrity of the high-voltage path. If the measured insulation resistance falls below a prescribed limit, indicative of potential degradation or leakage, the isolation monitoring circuit detects a leakage current above a threshold value. Upon such detection, the isolation monitoring circuit initiates disconnection of the external alternating current power source 5 from the UCCTI 1. A technical benefit of the isolation monitoring circuit integrated within the UCCTI 1 is that it enhances operational safety of the system 100 by preventing continued charging under hazardous insulation conditions. This reduces the risk of electric shock, prevents thermal damage to the rechargeable battery 2, and ensures compliance with high-voltage safety standards applicable to electric vehicles. Additionally, automatic disconnection triggered by the isolation monitoring circuit minimizes operator intervention and provides reliable protection against fault conditions during alternating current charging.

In another preferred embodiment, the UCCTI 1 comprises a plurality of inverter switches together with a modular fault-isolation subunit. The plurality of inverter switches form the active semiconductor stage of the UCCTI 1 that enables the bidirectional conversion between alternating current and direct current. During charging, the inverter switches regulate the conversion of alternating current supplied through the PMSM 3 into direct current for charging the rechargeable battery 2. During traction, the inverter switches modulate the direct current from the rechargeable battery 2 into alternating current waveforms suitable for driving the PMSM 3 as a propulsion motor.

The modular fault-isolation subunit is configured to disconnect an identified faulty inverter switch from active operation while permitting the remaining inverter switches to continue functioning. The subunit achieves this by electrically isolating the defective switch from the circuit, while maintaining conduction paths through the other operational switches. A technical benefit of integrating the fault-isolation subunit within the UCCTI 1 is that it prevents a localized switch failure from propagating into a complete converter failure, thereby preserving partial system functionality. This enhances the fault tolerance of the system 100, allows continued operation of the vehicle even under degraded conditions, and reduces downtime by enabling selective repair or replacement of individual inverter switch modules rather than the entire UCCTI 1 assembly.

In yet another embodiment, the PMSM 3 is further configured to operate as an inductive energy buffer during a regenerative braking event. When the vehicle undergoes deceleration, kinetic energy is converted into electrical energy by the PMSM 3 functioning in generator mode. Under such conditions, the PMSM 3 temporarily absorbs the resulting energy spike within its inductive windings before the energy is transferred to the rechargeable battery 2 through the UCCTI 1. By acting as an intermediate buffer, the PMSM 3 moderates sudden current surges and voltage rises that occur during regenerative braking. A technical benefit of this configuration is that it prevents overstressing of the rechargeable battery 2, enhances the stability of the UCCTI 1, and improves the efficiency of energy recovery. Moreover, the ability of the PMSM 3 to provide inductive buffering extends battery life by reducing exposure to high-current transients and ensures smoother regenerative braking performance within the system 100.

In a further preferred embodiment, the controller 4 comprises predictive thermal modelling logic that is configured to calculate a winding temperature rise of the PMSM 3 when operating in the transformer function. The predictive thermal modelling logic receives inputs relating to current density through the windings of the PMSM 3, together with at least one ambient condition such as ambient temperature or airflow. Based on these parameters, the controller 4 estimates the winding temperature rise during alternating current charging when the second three-phase terminal set 3b of the PMSM 3 is coupled to the external alternating current power source 5. If the calculated winding temperature deviates from a threshold limit, the controller 4 regulates the charging current by adjusting the operation of the UCCTI 1.

A technical benefit of integrating predictive thermal modeling logic within the controller 4 is that it enables proactive management of winding temperatures in the PMSM 3 rather than relying solely on reactive thermal protection. This enhances the safety of the system 100, prevents overheating of the PMSM 3 during prolonged charging cycles, and improves long-term reliability of the insulation system. Additionally, by dynamically regulating charging current, the controller 4 ensures efficient battery charging under diverse operating conditions while safeguarding the PMSM 3 against thermal degradation.

In an embodiment, the UCCTI 1 comprises an active front-end converter that is configured to regulate the input current drawn from the external alternating current power source 5. The active front-end converter shapes the input current waveform to follow the voltage waveform of the source 5, thereby maintaining a substantially unity power factor during charging operation. In addition, the active front-end converter compensates for harmonic distortion introduced by either the external alternating current power source 5 or the switching processes of the UCCTI 1 itself. The converter further operates to correct voltage imbalance in the external source 5, ensuring that the alternating current delivered to the PMSM 3 for transformer operation is stabilized prior to conversion into direct current for charging the rechargeable battery 2.

A technical benefit of incorporating the active front-end converter within the UCCTI 1 is that it improves the overall power quality of the system 100, thereby enabling efficient charging from a wide variety of grid conditions. Maintaining a unity power factor reduces reactive power draw from the source 5, which lowers transmission losses and enhances grid compatibility. The ability to compensate for harmonic distortion and voltage imbalance reduces stress on the PMSM 3, improves charging efficiency of the rechargeable battery 2, and minimizes electromagnetic interference with other components of the vehicle.

In another embodiment, the system 100 further comprises a pair of solid-state relays connected in series on a high-voltage power conduction path between the rechargeable battery 2 or the external alternating current power source 5 and the UCCTI 1. These solid-state relays are arranged to selectively open or close the high-voltage path under the command of the controller 4, thereby providing controlled connection and disconnection of the UCCTI 1 to the respective power source. During charging operation, the relays regulate the connection between the external alternating current power source 5 and the UCCTI 1, while during traction operation they regulate the connection between the rechargeable battery 2 and the UCCTI 1.

A technical benefit of integrating solid-state relays in the high-voltage path is that they provide fast, reliable, and wear-free switching compared to conventional electromechanical relays. This improves the responsiveness and safety of the system 100 by enabling immediate disconnection under fault conditions, while minimizing arcing and contact degradation. Furthermore, the use of solid-state relays enhances the longevity of the high-voltage switching elements, ensures smoother mode transitions between charging and traction, and contributes to the overall reliability of the UCCTI 1.

In yet another embodiment of the invention, the UCCTI 1 further comprises an arc suppression circuit configured to limit transient voltage spikes and suppress arcing during critical switching events. The arc suppression circuit is operable when the UCCTI 1 transitions between the charging mode, in which alternating current from the external power source 5 is converted to direct current for charging the rechargeable battery 2, and the traction mode, in which direct current from the rechargeable battery 2 is converted into alternating current for driving the PMSM 3. The arc suppression circuit is also operable when the high-voltage power conduction path is initially connected to the external alternating current power source 5, at which point inrush currents and potential voltage surges can give rise to arcing at the switching interfaces. A technical benefit of the arc suppression circuit integrated within the UCCTI 1 is that it reduces electrical stress on the inverter switches and solid-state relays, thereby extending their operational life. A further benefit is that it improves long-term system reliability by minimizing fault-induced downtime, while also allowing the vehicle to meet stringent high-voltage safety and electromagnetic compatibility standards. This improves overall reliability of both charging and traction functions and minimizes the risk of power interruptions caused by uncontrolled electrical transients.

In a further embodiment, the PMSM 3 comprises an electromagnetic rotor hold assembly configured to generate a magnetic clamping field during operation in the transformer function. When the second three-phase terminal set 3b of the PMSM 3 is connected to the external alternating current power source 5 in a charging mode, the electromagnetic rotor hold assembly is energized to create a static magnetic field that locks the rotor in position. By immobilizing the rotor through electromagnetic clamping rather than mechanical restraint, the PMSM 3 operates effectively as a transformer without producing unintended torque or mechanical oscillations. A technical benefit of the electromagnetic rotor hold assembly is that it prevents rotation of the PMSM 3 during charging without introducing frictional wear or mechanical stress, as would occur with mechanical locking devices. This ensures stable transformer operation, improves efficiency of the charging process by maintaining precise magnetic alignment, and contributes to the long-term durability of the PMSM 3. Furthermore, the electromagnetic locking mechanism can be dynamically controlled by the controller 4, enabling flexible activation and deactivation in synchronization with transitions between charging and traction modes within the system 100.

In a still further embodiment, the UCCTI 1 comprises a plurality of electromagnetic shielding layers that are disposed to attenuate electromagnetic emissions generated during inverter switching. The high-frequency switching of the inverter elements within the UCCTI 1 inherently produces electromagnetic radiation that can couple into adjacent circuits within the system 100. The shielding layers are strategically arranged around sensitive regions of the UCCTI 1 to confine and absorb these emissions. By containing the electromagnetic field, the shielding layers reduce the strength of interference signals that could otherwise propagate into other vehicle subsystems.

A technical benefit of the electromagnetic shielding layers is that they reduce the possibility of interference with vehicle communication components and control system elements. A further benefit is that they allow integration of the UCCTI 1 in compact vehicle platforms without requiring additional shielding housings, thereby lowering manufacturing cost and improving packaging flexibility within the vehicle system 100.

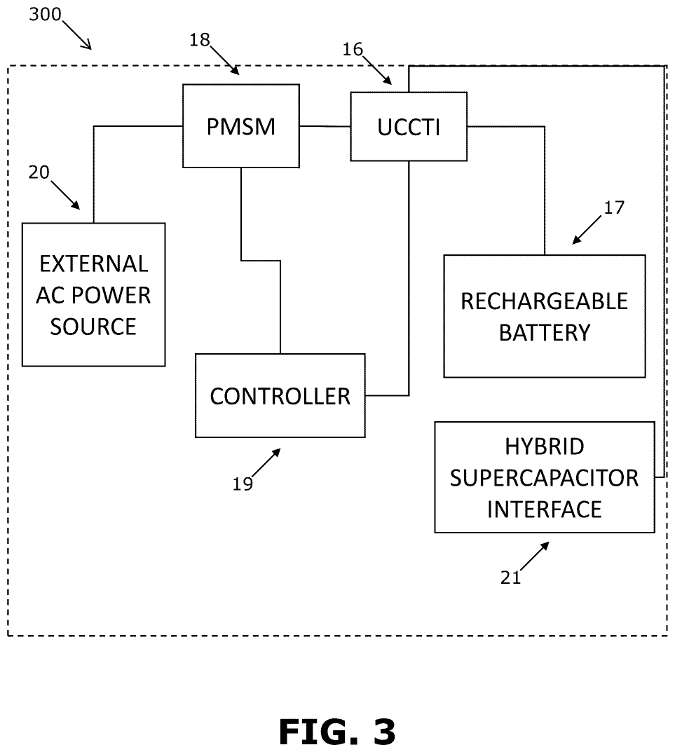

FIG. 3 illustrates a block diagram of an on-board charger and inverter system 300 for a vehicle. The system 300 comprises a UCCTI 16, a rechargeable battery 17, a dual three-phase PMSM 18, a controller 19, and an external alternating current power source 20. The PMSM 18 comprises a first three-phase terminal set electrically coupled to the UCCTI 16 and a second three-phase terminal set selectively connectable to the external alternating current power source 20. The UCCTI 16 is configured to perform bidirectional conversion between alternating current and direct current so that the rechargeable battery 17 may be charged during a charging mode and the PMSM 18 may be driven as a propulsion motor during a traction mode. The controller 19 coordinates operation of the UCCTI 16 and the PMSM 18, thereby enabling operation of the system 300 in the charging and traction modes described with reference to FIG. 1.

In addition to these components, the system 300 further comprises a hybrid supercapacitor interface (21) that is electrically connected in parallel with the rechargeable battery 17. The hybrid supercapacitor interface 21 is directly coupled to the UCCTI 16 such that both the rechargeable battery 17 and the supercapacitor interface 21 share the same electrical connection points. During a regenerative braking event, the PMSM 18 operates in generator mode to convert vehicle kinetic energy into electrical energy. The hybrid supercapacitor interface 21 is configured to absorb a high current surge generated under such conditions, thereby acting as a buffer before the energy is distributed to the rechargeable battery 17.

A technical benefit of the hybrid supercapacitor interface 21 is that it prevents overcurrent stress on the rechargeable battery 17 during regenerative braking by temporarily storing the energy spike and releasing it at a moderated rate. A further benefit is that it improves energy recovery efficiency while reducing battery degradation, which in turn enhances vehicle range, reduces long-term energy storage costs, and contributes to more sustainable operation of the system 300.

Referring again to FIG. 1, in a preferred embodiment, the UCCTI 1 comprises stackable inverter cartridges configured for modular installation. Each inverter cartridge forms a self-contained unit with its own switching elements and associated circuitry and is operable to share load current under the coordination of the controller 4. When multiple cartridges are installed, the controller 4 distributes the load current evenly across the cartridges so that the UCCTI 1 operates efficiently without overloading any single module.

The modular structure of the UCCTI 1 allows the number of inverter cartridges to be scaled by adding or removing cartridges according to the required power output capacity. For example, fewer cartridges may be installed for use in a light-duty two-wheeler vehicle, while additional cartridges may be incorporated for a heavy-duty electric vehicle requiring higher traction power. A technical benefit of the stackable inverter cartridge configuration is that it provides design flexibility across different vehicle platforms, reduces the need to redesign the UCCTI 1 for each application, and simplifies maintenance by allowing replacement of only a defective cartridge rather than the entire inverter assembly. Furthermore, current sharing among multiple cartridges enhances thermal performance and prolongs the operational life of the UCCTI 1, thereby improving the overall reliability of the system 100.

In the description of the present invention, it is also to be noted that, unless otherwise explicitly specified or limited, the terms “disposed,” “mounted,” and “connected” are to be construed broadly, and may for example be fixedly connected, detachably connected, or integrally connected, either mechanically or electrically. They may be connected directly or indirectly through intervening media, or they may be interconnected between two elements. The specific meaning of the above terms in the present invention can be understood in specific cases to those skilled in the art.

Modifications to embodiments and combination of different embodiments of the present disclosure described in the foregoing are possible without departing from the scope of the present disclosure as defined by the accompanying claims. Expressions such as “comprising”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural where appropriate.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the present disclosure, the drawings and the appended claims. In addition to variations and modifications in the component parts and/or arrangements, alternative uses will also be apparent to those skilled in the art.

We claim:

1. An on-board charger and inverter system (100, 200, 300) for a vehicle, comprising:
a unified charger cum traction inverter (UCCTI) (1, 9, 16) configured for bidirectional conversion between alternating current power and direct current power;
a rechargeable battery electrically coupled to the UCCTI (1, 9, 16);
a dual three-phase permanent magnet synchronous motor (PMSM) (3, 11, 18) comprising:
a first three-phase terminal set (3a) electrically coupled to the UCCTI (1, 9, 16); and
a second three-phase terminal set (3b) selectively connectable to an external
alternating current power source (5, 13, 20); and
a controller (4, 12, 19) operatively coupled to the UCCTI (1, 9, 16) and the dual three-phase PMSM (3, 11, 18), wherein the controller (4, 12, 19) configures:
the dual three-phase PMSM (3, 11, 18) to function as at least one of:
a transformer in a charging mode; and
a propulsion motor in a traction mode; and
the UCCTI (1, 9, 16) to operate in:
a first charging mode in which the second three-phase terminal set (3b) receives three-phase alternating current to configure the dual three-phase PMSM (3, 11, 18) to function as a step-down transformer and a filter transformer, and the UCCTI (1, 9, 16) converts the alternating current reduced by the dual three-phase PMSM (3, 11, 18) into direct current to charge the rechargeable battery;
a second charging mode in which the second three-phase terminal set (3b) receives single-phase alternating current across two terminals to configure the dual three-phase PMSM (3, 11, 18) as the step-down transformer and the filter transformer, and the UCCTI (1, 9, 16) converts the alternating current into direct current to charge the rechargeable battery;
a third traction mode in which the first three-phase terminal set (3a) receives the three-phase alternating current from the UCCTI (1, 9, 16) that is converted from the direct current of the rechargeable battery to drive the dual three-phase PMSM (3, 11, 18) into the traction mode; and
a fourth traction mode in which two terminals of the first three-phase terminal set (3a) receive single-phase alternating current from the UCCTI (1, 9, 16) that is converted from the direct current of the rechargeable battery to drive the dual three-phase PMSM (3, 11, 18) into the traction mode.

2. The system (100, 200, 300) of claim 1, wherein the transformer function of the dual three-phase PMSM (3, 11, 18) comprises at least one of:
a step-down transformer function to reduce external alternating current voltage prior to conversion into direct current; and
a filter transformer function to suppress harmonics present in the external alternating current power source (5, 13, 20) during charging.

3. The system (100, 200, 300) of claim 1, wherein the controller (4, 12, 19) is configured to isolate one three-phase terminal set of the dual three-phase PMSM (3, 11, 18) upon detection of a coil failure to permit continued operation with a remaining three-phase terminal set.

4. The system (100, 200, 300) of claim 1, wherein the dual three-phase PMSM (3, 11, 18) includes harmonic suppression coils to filter switching ripple when operating in the transformer function.

5. The system (100, 200, 300) of claim 1, further comprising a rotor-position lock configured to immobilize the dual three-phase PMSM (3, 11, 18) during operation of the dual three-phase PMSM (3, 11, 18) in the charging mode.

6. The system (100, 200, 300) of claim 1, wherein the dual three-phase PMSM (3, 11, 18) is integrated with liquid cooling channels and a plurality of thermal conduction fins to dissipate heat in the transformer function.

7. The system (100, 200, 300) of claim 1, further comprising a sensing unit (14) configured to detect at least one grid quality parameter selected from: a harmonic distortion, a voltage sag, and a frequency deviation, and a control unit (15) configured to adjust at least one charging parameter selected from: a charging current magnitude, a charging voltage level, and a charging rate in response to the detected at least one grid quality parameter.

8. The system (100, 200, 300) of claim 1, wherein the UCCTI (1, 9, 16) further comprises an isolation monitoring circuit configured to:
measure an insulation resistance between at least one high-voltage conductor and a ground during alternating current charging; and
initiate disconnection of the external alternating current power source (5, 13, 20) from the UCCTI (1, 9, 16) when leakage current above a threshold is detected.

9. The system (100, 200, 300) of claim 1, wherein the UCCTI (1, 9, 16) comprises:
a plurality of inverter switches; and
a modular fault-isolation subunit configured to disconnect a faulty inverter switch from operation while maintaining functional operation of remaining inverter switches.

10. The system (100, 200, 300) of claim 1, wherein the dual three-phase PMSM (3, 11, 18) is further configured to operate as an inductive energy buffer during a regenerative braking event and to temporarily absorb an energy spike prior to charging the rechargeable battery.

11. The system (100, 200, 300) of claim 1, wherein the controller (4, 12, 19) comprises predictive thermal modeling logic configured to calculate a winding temperature rise of the dual three-phase PMSM (3, 11, 18) during the transformer function based on a current density and at least one ambient condition to regulate a charging current when the calculated winding temperature deviates from a threshold limit.

12. The system (100, 200, 300) of claim 1, wherein the UCCTI (1, 9, 16) comprises an active front-end converter configured to regulate input current from the external alternating current power source (5, 13, 20), to maintain a unity power factor, and to compensate for a harmonic distortion when the external alternating current power source (5, 13, 20) exhibits a voltage imbalance.

13. The system (100, 200, 300) of claim 1, further comprising a pair of solid-state relays connected in series on a high-voltage power conduction path between the rechargeable battery or the external alternating current power source (5, 13, 20) and the UCCTI (1, 9, 16).

14. The system (100, 200, 300) of claim 1, wherein the UCCTI (1, 9, 16) further comprises an arc suppression circuit configured to limit a transient voltage spike and suppress arcing when at least one of:
the UCCTI (1, 9, 16) switches between the charging mode and the traction mode; and
the high-voltage power conduction path is connected to the external alternating current power source (5, 13, 20).

15. The system (100, 200, 300) of claim 1, wherein the UCCTI (1, 9, 16) comprises a plurality of electromagnetic shielding layers disposed to attenuate electromagnetic emissions generated by inverter switching, to reduce interference with at least one vehicle communication component and at least one control system element.

16. The system (100, 200, 300) of claim 1, wherein the UCCTI (1, 9, 16) comprises stackable inverter cartridges configured for modular installation, each cartridge operable to share load current under controller (4, 12, 19) coordination, and wherein the UCCTI (1, 9, 16) is scalable by adding or removing the cartridges to adapt power output capacity for different classes of electric vehicles.
